(19) United States
(12) Patent Application Publication
(10) Pub. No.: US 2020/0185482 A1
(43) Pub. Date: Jun. 11, 2020

(54) DISPLAY SUBSTRATE, METHOD FOR PREPARING THE SAME, AND DISPLAY DEVICE

(71) Applicant: BOE Technology Group Co., Ltd., Beijing (CN)

(72) Inventors: Guanyin WEN, Beijing (CN); Haidong WU, Beijing (CN); Xiaobo DU, Beijing (CN); Yansong LI, Beijing (CN)

(21) Appl. No.: 16/539,253

(22) Filed: Aug. 13, 2019

(30) Foreign Application Priority Data
Dec. 6, 2018 (CN) 201811487530.8

(51) Int. Cl. H01L 27/32; H01L 51/56

(52) U.S. Cl. CPC H01L 27/3272; H01L 51/56

(57) ABSTRACT

The present disclosure provides a display substrate, a method for preparing the same, and a display device. The display substrate includes: a substrate, a display unit arranged on the substrate, and an ultraviolet shielding layer arranged on a side of the display unit away from the substrate, wherein the ultraviolet shielding layer covers at least a portion of the display unit and includes at least two ultraviolet absorbing materials having different ultraviolet absorption bands.

### CROSS-REFERENCE TO RELATED APPLICATION

This application claims a priority to Chinese Patent Application No. 201811487530.8 filed on Dec. 6, 2018, the disclosures of which are incorporated in their entirety by reference herein.

### TECHNICAL FIELD

The present disclosure relates to the field of display technology, in particular, to a display substrate, a method for preparing the same and a display device.

### BACKGROUND

In recent years, an organic light-emitting device (OLED) has received widespread attention by people for their self-luminous, high efficiency, high brightness, low driving voltage, fast response, and large-area photoelectric display. However, when the OLED device is packaged with a chemical vapor deposition (CVD) and is used in sunlight, the OLED device is exposed to ultraviolet light, and ultraviolet light would cause deterioration of organic light-emitting materials in the OLED device, thereby affecting the lifetime of the OLED device.

### SUMMARY

A first aspect of the present disclosure provides a display substrate, including: a substrate, a display unit arranged on the substrate, an ultraviolet shielding layer arranged on a side of the display unit away from the substrate, wherein the ultraviolet shielding layer covers at least a portion of the display unit and includes at least two ultraviolet absorbing materials having different ultraviolet absorption bands.

Optionally, the ultraviolet absorption bands of the at least two ultraviolet absorbing materials are able to cover a wavelength range of 10 nm to 400 nm after being superimposed.

Optionally, the at least two ultraviolet absorbing materials have different refractive indexes, and the ultraviolet shielding layer includes at least two regions having different refractive indexes sequentially arranged along a direction perpendicular to the substrate.

Optionally, along a direction from proximate to the substrate to away from the substrate, a refractive index of the ultraviolet shielding layer gradually decreases.

Optionally, the ultraviolet shielding layer includes a first ultraviolet absorbing material and a second ultraviolet absorbing material, with a refractive index of the first ultraviolet absorbing material being greater than a refractive index of the second ultraviolet absorbing material; and the at least two regions include a first region, a second region, and a third region sequentially arranged along a direction from proximate to the substrate to away from the substrate, with the first region including the first ultraviolet absorption material, the second region including the first ultraviolet absorbing material and the second ultraviolet absorbing material, and the third region including the second ultraviolet absorbing material.

Optionally, the ultraviolet shielding layer includes a first ultraviolet absorbing material and a second ultraviolet absorbing material, with a refractive index of the first ultraviolet absorbing material being greater than a refractive index of the second ultraviolet absorbing material; and the at least two regions includes a fourth region, a fifth region, and a sixth region sequentially arranged in a direction sequentially arranged along a direction from proximate to the substrate to away from the substrate, in which a mass ratio of the first ultraviolet absorbing material to the second ultraviolet absorbing material in the fourth region is X1 that is greater than 1, a mass ratio of the first ultraviolet absorbing material to the second ultraviolet absorbing material in the sixth region is X3 that is less than 1, and a mass ratio of the first ultraviolet absorbing material to the second ultraviolet absorbing material in the fifth region is X2 that is less than X1 and greater than X3.

Optionally, the ultraviolet absorbing material includes a triphenylamine-based organic material, a material with an aza-aromatic ring structure or a triamine derivative with a carbazole-based benzo-conjugated structure.

Optionally, the ultraviolet absorbing material has a refractive index of 1.8 to 2.2.

Optionally, the ultraviolet shielding layer covers the entire region of the display unit.

A second aspect of the present disclosure provides a display device including the above display substrate.

A third aspect of the present disclosure provides a method for preparing a display substrate, including: preparing a display unit on the substrate; forming an ultraviolet shielding layer on a side of the display unit away from the substrate, in which the ultraviolet shielding layer covers at least a portion of the display unit and includes at least two ultraviolet absorbing materials having different ultraviolet absorption bands.

Optionally, the forming the ultraviolet shielding layer on the side of the display unit away from the substrate includes: forming the ultraviolet shielding layer by vapor deposition of the at least two ultraviolet absorbing materials.

Optionally, the forming the ultraviolet shielding layer by vapor deposition of the at least two ultraviolet absorbing materials includes: vapor depositing the ultraviolet absorbing material by an evaporation source that is in one-to-one correspondence with the ultraviolet absorbing material to form the ultraviolet shielding layer.

Optionally, the at least two ultraviolet absorbing materials have different refractive indexes, and the ultraviolet shielding layer includes at least two regions sequentially arranged along a direction perpendicular to the substrate, with the at least two regions having different refractive indexes, and in which the forming the ultraviolet shielding layer includes: forming the ultraviolet shielding layer by controlling a vapor deposition rate and/or a vapor deposition time of each of the evaporation sources.

Optionally, the at least two ultraviolet absorbing materials include a first ultraviolet absorbing material and a second ultraviolet absorbing material, with a refractive index of the first ultraviolet absorbing material being greater than a refractive index of the second ultraviolet absorbing material, and along a direction from proximate to the substrate to away from the substrate, a refractive index of the ultraviolet shielding layer gradually decreases, and in which the forming the ultraviolet shielding layer includes: throughout a first period of a vapor deposition cycle, controlling an evaporation source having the first ultraviolet absorbing material to perform vapor deposition, and an evaporation source having the second ultraviolet absorbing material to stop vapor deposition; throughout a second period of the vapor deposition cycle, controlling the evaporation source having the first ultraviolet absorbing material and the evaporation source having the second ultraviolet absorbing material to perform vapor deposition together; and throughout a third period of the vapor deposition cycle, controlling the evaporation source having the first ultraviolet absorbing material to stop vapor deposition, and the evaporation source having the second ultraviolet absorbing material to perform vapor deposition.

Optionally, the at least two ultraviolet absorbing materials include a first ultraviolet absorbing material and a second ultraviolet absorbing material, with a refractive index of the first ultraviolet absorbing material being greater than a refractive index of the second ultraviolet absorbing material, and along a direction from proximate to the substrate to away from the substrate, a refractive index of the ultraviolet shielding layer gradually decreases, and in which the forming the ultraviolet shielding layer includes: controlling the evaporation source having the first ultraviolet absorbing material and the evaporation source having the second ultraviolet absorbing material to perform vapor deposition together; controlling a vapor deposition rate of the evaporation source having the first ultraviolet absorbing material to gradually decrease; and controlling a vapor deposition rate of the evaporation source having the second ultraviolet absorbing material to gradually increase.

Optionally, the forming the ultraviolet shielding layer by vapor deposition of the at least two ultraviolet absorbing materials includes: mixing the at least two ultraviolet absorbing materials to prepare a mixed material; and vapor depositing the mixed material by an evaporation source to form the ultraviolet shielding layer.

### BRIEF DESCRIPTION OF THE DRAWINGS

The drawings described herein are intended to provide a further understanding of the present disclosure, and constitute a part of this disclosure. The illustrative embodiments of the present disclosure and the description thereof are intended to illustrate the present disclosure, and do not constitute an improper limitation of the present disclosure. In the drawings:

FIG. 1 is a schematic view showing a display substrate according to an embodiment of the present disclosure.

FIG. 2 is a schematic view showing the absorption coefficient of two ultraviolet absorbing materials after being superposed.

FIG. 3 is a schematic view showing the preparation of an ultraviolet shielding layer by using one evaporation source according to an embodiment of the present disclosure.

FIG. 4 is a schematic view showing the preparation of an ultraviolet shielding layer by using several evaporation sources according to an embodiment of the present disclosure.

FIG. 5 is a first schematic view showing an ultraviolet shielding layer according to an embodiment of the present disclosure.

FIG. 6 is a second schematic view showing an ultraviolet shielding layer according to an embodiment of the present disclosure.

### DETAILED DESCRIPTION

In order to further illustrate the display substrate, the method for preparing the same and the display device provided by the embodiments of the present disclosure, the present disclosure will be described in detail hereinafter in conjunction with the drawings.

An OLED device is a self-luminous device that does not require a backlight and emits light by driving a light-emitting material layer inside with the electrode. However, because of this, its internal light-emitting material layer determines the lifetime of the OLED device. Since the light-emitting material layer is generally formed by using an organic light-emitting material in combination with some dopants, the organic light-emitting material and the dopant are easily decomposed and deteriorated under the irradiation of ultraviolet light, resulting in a decrease in the lifetime of the light-emitting material layer.

In the related art, when the OLED device is prepared, the thin film packaging process is performed at the end. The thin film packaging process generally uses a CVD process, and a lot of ultraviolet light is present in a chamber for performing the CVD process. Thus, the OLED device is directly exposed to ultraviolet light when the OLED device is subjected to thin film packaging, and the ultraviolet light will cause redox reaction of the organic light-emitting material, thereby affecting the lifetime of the OLED device. Moreover, after the OLED device is packaged and when the OLED device is exposed to sunlight, the ultraviolet light contained in the sunlight also affects the light-emitting material layer in the OLED device, thereby affecting the lifetime of the OLED device.

Based on the above problems, the inventors of the present disclosure have found that a film layer capable of shielding ultraviolet light can be formed on the surface of the OLED device before the thin film packaging of the OLED device, and the film layer may use an ultraviolet absorbing material having a certain ultraviolet absorption capacity, however, few ultraviolet absorbing materials are capable of absorbing ultraviolet light in the entire ultraviolet light band. Therefore, the inventors of the present disclosure have further found that two or more ultraviolet absorbing materials can be used for forming the film layer for shielding ultraviolet light by co-vapor deposition, and thus the film layer is capable of shielding ultraviolet light in a plurality of ultraviolet bands, thereby better avoiding the influence of ultraviolet light on the OLED device, and achieving the purpose of improving the lifetime of the OLED device.

Referring to FIG. 1, an embodiment of the present disclosure provides a display substrate, including: a substrate 1, a display unit 2 arranged on the substrate 1, and an ultraviolet shielding layer 3 arranged on a side of the display unit 2 away from the substrate 1, wherein the ultraviolet shielding layer 3 covers at least a portion of the display unit 2 and includes at least two ultraviolet absorbing materials having different ultraviolet absorption bands.

Specifically, when the display substrate is prepared, the display unit 2 may be first formed on the substrate 1; then the ultraviolet shielding layer 3 is formed on the display unit 2 by co-vapor depositing at least two ultraviolet absorbing materials capable of absorbing ultraviolet light in different wavelength bands, in which ultraviolet shielding layer 3 is capable of covering at least a portion of the display unit 2; and then a thin film packaging process is performed. The thin film packaging process can form a packaging film on the display unit 2 on which the ultraviolet shielding layer 3 is formed by a CVD process. Since the ultraviolet shielding layer 3 is formed on the display unit 2, in the case that the thin film is packaged by the CVD process, the ultraviolet shielding layer 3 is capable of absorbing ultraviolet light in various wavelength bands in the chamber, thereby avoiding the ultraviolet light in the chamber to affect the light-emitting material layer in the display unit 2.

When the above display substrate is applied in an environment having ultraviolet light, the ultraviolet shielding layer 3 in the display substrate is capable of absorbing ultraviolet light in the environment, thereby avoiding ultraviolet light in the environment to affect the light-emitting material layer in the display unit 2.

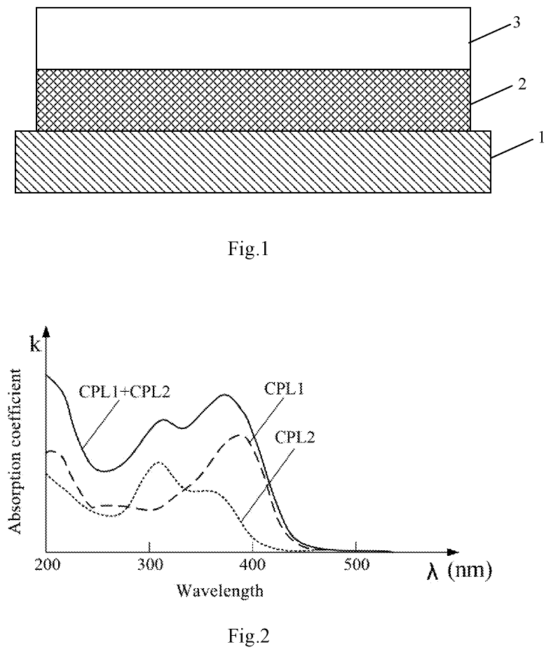

More specifically, as shown in FIG. 2, the ultraviolet shielding layer 3 includes two ultraviolet absorbing materials, in which the first ultraviolet absorbing material CPL1 has a strong absorption capacity to ultraviolet light in the band near the 380 nm, and the second ultraviolet absorbing material CPL2 has a strong absorption capacity to ultraviolet light in the band near the 310 nm. When CPL1 and CPL2 are co-vapor deposited, an ultraviolet shielding layer 3 having a strong ultraviolet absorption capacity to the band in the range of 300 nm to 400 nm can be obtained (the solid line in FIG. 2 represents the absorption coefficient k corresponding to the ultraviolet shielding layer 3 formed by CPL1 and CPL2). It should be noted that, in FIG. 2, the abscissa represents the wavelength, and the ordinate represents the absorption coefficient.

According to the specific structure, the preparation process, and the application process of the display substrate, in the display substrate provided by the embodiment of the present disclosure, the ultraviolet shielding layer 3 that is capable of covering at least a portion of the display unit 2 is formed on the display unit 2, and the ultraviolet shielding layer 3 includes at least two ultraviolet absorbing materials having different ultraviolet absorbing bands. Thus, when the display substrate is subjected to thin film packaging, the ultraviolet shielding layer 3 is capable of absorbing different ultraviolet absorbing bands in the chamber in which the packaging process is performed, thereby avoiding the influence of ultraviolet light in the chamber of the packaging process on the light-emitting material layer included in the display unit 2 of the display substrate when the display substrate is packaged. Moreover, when the packaged display substrate is applied in an external environment, the ultraviolet shielding layer 3 in the display substrate is also capable of absorbing ultraviolet light of different wavelength bands in the external environment, thereby avoiding ultraviolet light in the external environment to affect the light-emitting material layer included in the display unit 2 of the display substrate. Therefore, in the display substrate provided by the embodiment of the present disclosure, the ultraviolet shielding layer 3 is capable of absorbing ultraviolet light in different wavelength bands, so that the display substrate can avoid the influence of the ultraviolet light on the light-emitting material layer included therein during the packaging process and during the use, such that the lifetime of the display substrate is well guaranteed.

Further, the ultraviolet absorption bands corresponding to at least two ultraviolet absorbing materials included in the ultraviolet shielding layer 3 in the above embodiment may be set to be capable of covering the wavelength range of 10 nm to 400 nm after being superimposed.

Specifically, the above setting manner enables the formed ultraviolet shielding layer 3 to absorb the ultraviolet light of all band, so that the ultraviolet light of the external wavelength bands can be absorbed by the ultraviolet shielding layer 3 regardless of the display substrate in the packaging process or in practical applications, thereby further avoiding the influence of ultraviolet light on the light-emitting material layer included in the display unit 2 of the display substrate, and ensuring the lifetime of the display substrate.

In some embodiments, the refractive index of the at least two ultraviolet absorbing materials included in the ultraviolet shielding layer 3 in the above embodiment may be set to be different. The ultraviolet shielding layer 3 has at least two regions having different refractive indexes, in which the at least two regions are sequentially arranged in a direction perpendicular to the substrate 1.

Specifically, when the ultraviolet shielding layer 3 is prepared, in addition to considering the absorption band of ultraviolet light, the ultraviolet absorbing material used may be set to have different refractive indexes, so that the ultraviolet shielding layer 3 having different refractive indexes in at least two regions may be prepared according to the actual light-emitting requirements of the display substrate. Thus, the prepared ultraviolet shielding layer 3 is more suitable for the light-emitting requirement of the display substrate, thereby better improving the light-emitting performance of the display substrate.

More specifically, the ultraviolet shielding layer 3 may be formed by co-vapor deposition of ultraviolet absorbing materials having different refractive indexes, and the refractive index of the ultraviolet absorbing material may be optionally between 1.8 and 2.2. Moreover, when a plurality of ultraviolet absorbing materials having different refractive indexes are co-vapor deposited, the vapor deposition rate of each ultraviolet absorbing material can be controlled by continuously adjusting the switching degree of the vapor deposition switch above the evaporation source 4 during the vapor deposition, thereby achieving ultraviolet shielding layers 3 having different refractive index distributions.

Further, the refractive index of the ultraviolet shielding layer 3 may gradually decrease along a direction from proximate to the substrate 1 to away from the substrate 1.

Specifically, the refractive index of the ultraviolet shielding layer 3 is set to gradually decreases along a direction from proximate to the substrate 1 to away from the substrate 1, so that the ultraviolet shielding layer 3 has a light collecting effect. Thus, when the ultraviolet shielding layer 3 is formed on the display unit 2 of the display device, the light-emitting efficiency of the display substrate can be better improved.

In some embodiments, the ultraviolet shielding layer 3 includes a first ultraviolet absorbing material and a second ultraviolet absorbing material, in which a refractive index of the first ultraviolet absorbing material is greater than a refractive index of the second ultraviolet absorbing material; and the at least two regions include a first region 31, a second region 32, and a third region 33 sequentially arranged along a direction from proximate to the substrate 1 to away from the substrate 1, in which the first region 31 includes the first ultraviolet absorption material, the second region 32 includes the first ultraviolet absorbing material and the second ultraviolet absorbing material, and the third region 33 includes the second ultraviolet absorbing material.

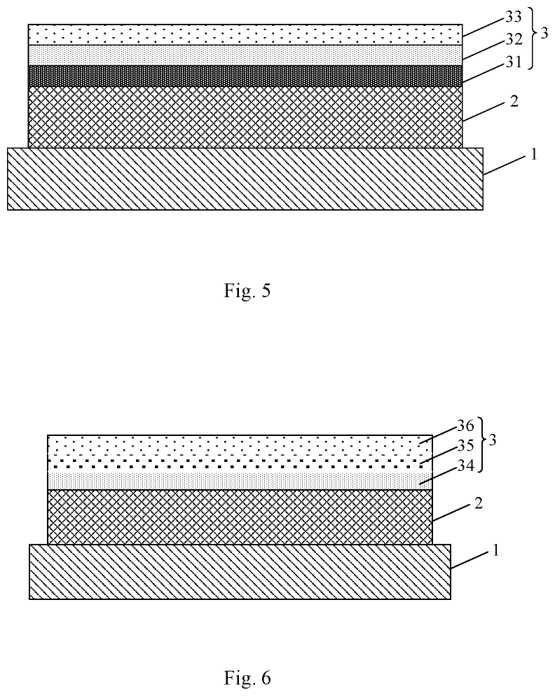

Specifically, as shown in FIG. 5, when the ultraviolet shielding layer 3 provided in the above embodiment is prepared, throughout the first period of a vapor deposition cycle, an evaporation source 4 corresponding to the first ultraviolet absorbing material is controlled to perform vapor deposition, and an evaporation source 4 corresponding to the second ultraviolet absorbing material is controlled to stop vapor deposition, and thus the first region 31 including the first ultraviolet absorbing material is formed on the display unit 2 of the display substrate; throughout the second period of the vapor deposition cycle, the evaporation source 4 corresponding to the first ultraviolet absorbing material and the evaporation source 4 corresponding to the second ultraviolet absorbing material are controlled to perform vapor deposition together, and thus a second region 32 including the first ultraviolet absorbing material and the second ultraviolet absorbing material is continuously formed on the side of the first region 31 facing away from the display unit 2; and throughout a third period of the vapor deposition cycle, the evaporation source 4 corresponding to the first ultraviolet absorbing material is controlled to stop vapor deposition, and an evaporation source 4 corresponding to the second ultraviolet absorbing material is controlled to perform vapor deposition, and thus a third region 33 including the second ultraviolet absorbing material is continuously formed on the side of the second region 32 facing away from the display unit 2. In the ultraviolet shielding layer 3 formed in the above manner, the refractive indexes of the first region 31, the second region 32, and the third region 33 are sequentially decreased, thereby forming an ultraviolet shielding layer 3 having a refractive index gradually decreasing in a direction from proximate to the substrate 1 to away from the substrate 1.

In some embodiments, the ultraviolet shielding layer 3 includes a first ultraviolet absorbing material and a second ultraviolet absorbing material, in which a refractive index of the first ultraviolet absorbing material is greater than a refractive index of the second ultraviolet absorbing material; and the at least two regions includes a fourth region 34, a fifth region 35, and a sixth region 36 sequentially arranged in a direction sequentially arranged along a direction from proximate to the substrate 1 to away from the substrate 1, in which a mass ratio of the first ultraviolet absorbing material to the second ultraviolet absorbing material in the fourth region 34 is X1 that is greater than 1, a mass ratio of the first ultraviolet absorbing material to the second ultraviolet absorbing material in the sixth region 36 is X3 that is less than 1, and a mass ratio of the first ultraviolet absorbing material to the second ultraviolet absorbing material in the fifth region 35 is X2 that is less than X1 and greater than X3.

Specifically, as shown in FIG. 6, when the ultraviolet shielding layer 3 provided in the above embodiment is prepared, the evaporation source 4 corresponding to the first ultraviolet absorbing material and the evaporation source 4 corresponding to the second ultraviolet absorbing material can be controlled to perform vapor deposition together, and simultaneously the vapor deposition rate of the evaporation source 4 corresponding to the first ultraviolet absorbing material is controlled to gradually decrease and the vapor deposition rate of the evaporation source 4 corresponding to the second ultraviolet absorbing material is controlled to gradually increase. Thus, in the initial period of the whole vapor deposition cycle, the vapor deposition rate of the first ultraviolet absorbing material is relatively fast and the vapor deposition rate of the second ultraviolet absorbing material is relatively slow, thereby forming the fourth region 34, in which a mass ratio of the first ultraviolet absorbing material to the second ultraviolet absorbing material in the fourth region 34 is X1 that is greater than 1. In the middle period of the whole vapor deposition cycle, the vapor deposition rate of the first ultraviolet absorbing material and the vapor deposition rate of the second ultraviolet absorbing material are similar, thereby forming the fifth region 35, in which a mass ratio of the first ultraviolet absorbing material to the second ultraviolet absorbing material in the fifth region 35 is X2 that is less than X1 and greater than 1. In the final period of the whole vapor deposition cycle, the vapor deposition rate of the first ultraviolet absorbing material is relatively slow and the vapor deposition rate of the second ultraviolet absorbing material is relatively fast, thereby forming the sixth region 36, in which a mass ratio of the first ultraviolet absorbing material to the second ultraviolet absorbing material in the sixth region 36 is X3 that is less than 1. In the ultraviolet shielding layer 3 formed in the above manner, the refractive indexes of the fourth region 34, the fifth region 35, and the sixth region 36 are sequentially decreased, thereby forming an ultraviolet shielding layer 3 having a refractive index gradually decreasing in a direction from proximate to the substrate 1 to away from the substrate 1.

The ultraviolet absorbing material 3 may be selected from various ultraviolet absorbing materials. Illustratively, the ultraviolet absorbing material may include: a triphenylamine-based organic material, a material with an aza-aromatic ring structure or a triamine derivative with a carbazole-based benzo-conjugated structure. These types of materials have a good absorption effect on ultraviolet light, and have a poor absorption effect on light in other bands than the ultraviolet band, for example, visible light. Therefore, when the ultraviolet shielding layer 3 is formed by using these types of ultraviolet absorbing materials, the ultraviolet shielding layer 3 produced not only has a good ultraviolet absorbing effect, but also does not affect the normal display of the display substrate.

One embodiment of the present disclosure further provides a display device including the display substrate provided by the above embodiment.

In the display substrate provided by the above embodiment, the ultraviolet shielding layer 3 that is capable of covering at least a portion of the display unit 2 is formed on the display unit 2, and the ultraviolet shielding layer 3 is capable of absorbing ultraviolet light in different wavelength bands, so that the display substrate can avoid the influence of the ultraviolet light on the light-emitting material layer included therein during the packaging process and during the use, such that the lifetime of the display substrate is well guaranteed. Therefore, the display device provided by the embodiment of the present disclosure, includes the display substrate provided by the above embodiment, and thus has the above technical effects.

The embodiment of the present disclosure further provides a method for preparing a display substrate, which is used for preparing the display substrate provided by the above embodiments, and the method includes: preparing a display unit 2 on the substrate 1; forming an ultraviolet shielding layer 3 on a side of the display unit 2 away from the substrate 1, in which the ultraviolet shielding layer 3 covers at least a portion of the display unit 2, and includes at least two ultraviolet absorbing materials having different ultraviolet absorption bands.

Specifically, the display unit 2 may be first prepared on the substrate 1, and the display unit 2 generally includes a thin film transistor array layer, an anode layer, a light-emitting material layer, a cathode layer, and the like; then the ultraviolet shielding layer 3 is formed on the display unit 2 with at least two ultraviolet absorbing materials being capable of absorbing ultraviolet light in different wavelength bands, in which ultraviolet shielding layer 3 is capable of covering at least a portion of the display unit 2; and then a thin film packaging process is performed. The thin film packaging process can form a packaging film on the display unit 2 on which the ultraviolet shielding layer 3 is formed by a CVD process. Since the ultraviolet shielding layer 3 is formed on the display unit 2, in the case that the thin film is packaged by the CVD process, the ultraviolet shielding layer 3 is capable of absorbing ultraviolet light in various wavelength bands in the chamber, thereby avoiding the ultraviolet light in the chamber to affect the light-emitting material layer in the display unit 2.

When the display substrate produced by the above method is applied in an environment having ultraviolet light, the ultraviolet shielding layer 3 in the display substrate is capable of absorbing ultraviolet light in the environment, thereby avoiding ultraviolet light in the environment to affect the light-emitting material layer in the display unit 2.

In the display substrate produced by the method provided by the embodiment of the present disclosure, the ultraviolet shielding layer 3 is formed on the display unit 2, and the ultraviolet shielding layer 3 is capable of covering at least a portion of the display unit 2 and includes at least two ultraviolet absorbing materials having different ultraviolet absorbing bands. Thus, when the display substrate is subjected to thin film packaging, the ultraviolet shielding layer 3 is capable of absorbing different ultraviolet absorbing bands in the chamber in which the packaging process is performed, thereby avoiding the influence of ultraviolet light in the chamber of the packaging process on the light-emitting material layer included in the display unit 2 of the display substrate when the display substrate is packaged. Moreover, when the display substrate produced by the method provided by the embodiment of the present disclosure is applied in an external environment, the ultraviolet shielding layer 3 of the display substrate is also capable of absorbing ultraviolet light with different wavelength bands in the external environment, thereby avoiding ultraviolet light in the external environment to affect the light-emitting material layer included in the display unit 2 of the display substrate. Therefore, in the display substrate prepared by the method provided by the embodiment of the present disclosure, the ultraviolet shielding layer 3 is capable of absorbing ultraviolet light with different wavelength bands, so that the display substrate can avoid the influence of the ultraviolet light on the light-emitting material layer included therein during the packaging process and during the use, such that the lifetime of the display substrate is well guaranteed.

It is noted that when the ultraviolet shielding layer 3 is formed on the display unit 2 by at least two ultraviolet absorbing materials capable of absorbing ultraviolet light with different wavelength bands, optionally, the ultraviolet absorption bands of the at least two ultraviolet absorbing materials are able to cover a wavelength range of 10 nm to 400 nm after being superimposes. Thus, this enables the formed ultraviolet shielding layer 3 to absorb the ultraviolet light with all bands, so that the external ultraviolet light with the wavelength bands can be absorbed by the ultraviolet shielding layer 3 regardless of the display substrate in the packaging process or in practical applications, thereby further avoiding the influence of ultraviolet light on the light-emitting material layer included in the display unit 2 in the display substrate, and ensuring the lifetime of the display substrate.

In addition, optionally, the ultraviolet shielding layer 3 can cover the entire area of the display unit 2, so that the ultraviolet shielding layer 3 can more comprehensively protect the display unit 2, and better avoid the influence of ultraviolet light on the display unit 2.

There are various preparation processes of the ultraviolet shielding layer 3 described above. In some embodiments, the step of forming the ultraviolet shielding layer 3 on the display unit 2 may include forming the ultraviolet shielding layer 3 by vapor deposition with at least two ultraviolet absorbing materials.

Specifically, the ultraviolet shielding layer 3 can be formed by co-vapor depositing at least two ultraviolet absorbing materials which are capable of absorbing ultraviolet light with different wavelength bands, so that the ultraviolet shielding layer 3 formed can better cover the display unit 2, and the formed thickness of the ultraviolet shielding layer 3 and the distribution regions of various ultraviolet absorbing materials can also be better controlled according to actual needs.

There are various specific vapor deposition manners for forming the ultraviolet shielding layer 3 by vapor deposition of at least two ultraviolet absorbing materials. Two specific vapor deposition manners are listed below, and the vapor deposition process and the advantageous effects are described.

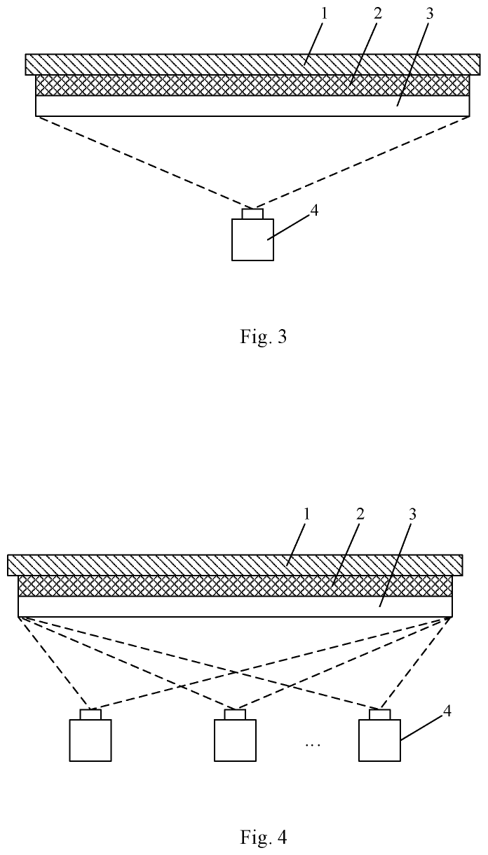

In a first manner, as shown in FIG. 3, the step of forming the ultraviolet shielding layer 3 by vapor deposition of at least two ultraviolet absorbing materials includes: mixing at least two ultraviolet absorbing materials to prepare a mixed material; and vapor depositing the mixed material with the evaporation source 4 to form an ultraviolet shielding layer 3.

Specifically, when the ultraviolet shielding layer 3 is produced by the first manner described above, at least two ultraviolet absorbing materials which are capable of absorbing ultraviolet light of different wavelength bands may be first mixed to prepare a mixed material, and then the mixed material is vapor deposited with the evaporation source 4 to form the ultraviolet shielding layer 3 that is capable of absorbing ultraviolet light with various bands.

When the ultraviolet shielding layer 3 is produced by the first manner described above, it is only necessary to perform vapor deposition using one evaporation source, and thus the vapor deposition process is simple and the cost is low.

It should be noted that when the ultraviolet absorbing material is selected, in addition to make a difference in the respective ultraviolet absorbing bands to be satisfied by the various ultraviolet absorbing materials, the thermal parameters corresponding to the respective ultraviolet absorbing materials can be relatively close, which is more favorable for forming a good vapor deposition effect.

In a second manner, as shown in FIG. 4, the step of forming the ultraviolet shielding layer 3 by vapor deposition of at least two ultraviolet absorbing materials may include: vapor depositing the corresponding ultraviolet absorbing material with an evaporation source 4 that is in one-to-one correspondence with the ultraviolet absorbing material to form the ultraviolet shielding layer 3.

Specifically, when the ultraviolet shielding layer 3 is produced by the second manner described above, each ultraviolet absorbing material can be arranged in the corresponding evaporation source 4, and the corresponding ultraviolet absorbing material can be separately vapor-deposited with each evaporation source 4 to form the ultraviolet shielding layer 3.

When the ultraviolet shielding layer 3 is produced by the second manner described above, the vapor deposition time and the vapor deposition rate of the various ultraviolet absorbing materials can be controlled separately, so that the distribution regions and the vapor deposition time of various ultraviolet absorbing materials in the formed ultraviolet shielding layer 3 can be controlled according to actual needs, thereby forming an ultraviolet shielding layer 3 that is more suitable for actual needs.

Further, when the refractive indexes of the at least two ultraviolet absorbing materials are different, the ultraviolet shielding layer 3 has at least two regions having different refractive indexes, and the at least two regions are sequentially arranged in a direction perpendicular to the substrate 1, the step of forming the ultraviolet shielding layer 3 in the second manner described above includes forming the ultraviolet shielding layer 3 by controlling the vapor deposition rate and/or the evaporation time of each evaporation source 4.

Specifically, when the ultraviolet shielding layer 3 is prepared, in addition to considering the absorption band of ultraviolet light, the ultraviolet absorbing material used may be set to have different refractive indexes, so that the ultraviolet shielding layer 3 having different refractive indexes in at least two regions may be prepared according to the actual light-emitting requirements of the display substrate. Thus, the prepared ultraviolet shielding layer 3 is more suitable for the light-emitting requirement of the display substrate, thereby better improving the light-emitting performance of the display substrate.

More specifically, when the ultraviolet shielding layer 3 is formed by the second manner described above, the corresponding ultraviolet absorbing material can be vapor-deposited with the evaporation source 4 that is in one-to-one correspondence with the ultraviolet absorbing material, and thus the vapor deposition time and the vapor deposition rate of various ultraviolet absorbing materials can be controlled individually. The vapor deposition rate and/or the vapor deposition time of each evaporation source 4 can be controlled according to the distribution requirements of the regions having different refractive indexes in the ultraviolet shielding layer 3 to be formed, thereby achieving the ultraviolet shielding layer 3 having different refractive index distribution.

Further, the refractive index of the ultraviolet shielding layer 3 is set to gradually decreases along a direction from proximate to the substrate 1 to away from the substrate 1, so that the ultraviolet shielding layer 3 has a light collecting effect. Thus, when the ultraviolet shielding layer 3 is formed on the display unit 2 of the display device, the light-emitting efficiency of the display substrate can be better improved.

In some embodiments, when the at least two ultraviolet absorbing materials included in the ultraviolet shielding layer 3 in the above embodiment include the first ultraviolet absorbing material and the second ultraviolet absorbing material, in which a refractive index of the first ultraviolet absorbing material is greater than a refractive index of the second ultraviolet absorbing material, and along a direction from proximate to the substrate to away from the substrate, a refractive index of the ultraviolet shielding layer gradually decreases, the forming the ultraviolet shielding layer may include: throughout a first period of a vapor deposition cycle, an evaporation source 4 corresponding to the first ultraviolet absorbing material is controlled to perform vapor deposition, and an evaporation source 4 corresponding to the second ultraviolet absorbing material is controlled to stop vapor deposition; throughout a second period of the vapor deposition cycle, an evaporation source 4 corresponding to the first ultraviolet absorbing material and an evaporation source 4 corresponding to the second ultraviolet absorbing material are controlled to perform vapor deposition together; and throughout a third period of the vapor deposition cycle, an evaporation source 4 corresponding to the first ultraviolet absorbing material is controlled to stop vapor deposition, and an evaporation source 4 corresponding to the second ultraviolet absorbing material is controlled to perform vapor deposition.

Specifically, as shown in FIG. 5, throughout the first period of the vapor deposition cycle, an evaporation source 4 corresponding to the first ultraviolet absorbing material is controlled to perform vapor deposition, and an evaporation source 4 corresponding to the second ultraviolet absorbing material is controlled to stop vapor deposition, and thus the first region 31 including the first ultraviolet absorbing material is formed on the display unit 2 of the display substrate; throughout the second period of the vapor deposition cycle, the evaporation source 4 corresponding to the first ultraviolet absorbing material and the evaporation source 4 corresponding to the second ultraviolet absorbing material are controlled to perform vapor deposition together, and thus a second region 32 including the first ultraviolet absorbing material and the second ultraviolet absorbing material is continuously formed on the side of the first region 31 facing away from the display unit 2; and throughout a third period of the vapor deposition cycle, the evaporation source 4 corresponding to the first ultraviolet absorbing material is controlled to stop vapor deposition, and an evaporation source 4 corresponding to the second ultraviolet absorbing material is controlled to perform vapor deposition, and thus a third region 33 including the second ultraviolet absorbing material is continuously formed on the side of the second region 32 facing away from the display unit 2. In the ultraviolet shielding layer 3 formed in the above manner, the refractive indexes of the first region 31, the second region 32, and the third region 33 are sequentially decreased, thereby forming an ultraviolet shielding layer 3 having a refractive index gradually decreasing in a direction from proximate to the substrate 1 to away from the substrate 1.

In still other embodiments, when the at least two ultraviolet absorbing materials included in the ultraviolet shielding layer 3 in the above embodiment include the first ultraviolet absorbing material and the second ultraviolet absorbing material, in which a refractive index of the first ultraviolet absorbing material is greater than a refractive index of the second ultraviolet absorbing material, and along a direction from proximate to the substrate to away from the substrate, a refractive index of the ultraviolet shielding layer gradually decreases, the forming the ultraviolet shielding layer may further include: controlling the evaporation source 4 corresponding to the first ultraviolet absorbing material and the evaporation source 4 corresponding to the second ultraviolet absorbing material to perform vapor deposition together; controlling a vapor deposition rate of the evaporation source 4 corresponding to the first ultraviolet absorbing material to gradually decrease; and controlling a vapor deposition rate of the evaporation source 4 corresponding to the second ultraviolet absorbing material to gradually increase.

Specifically, as shown in FIG. 6, the evaporation source 4 corresponding to the first ultraviolet absorbing material and the evaporation source 4 corresponding to the second ultraviolet absorbing material can be controlled to perform vapor deposition together, and simultaneously the vapor deposition rate of the evaporation source 4 corresponding to the first ultraviolet absorbing material is controlled to gradually decrease and the vapor deposition rate of the evaporation source 4 corresponding to the second ultraviolet absorbing material is controlled to gradually increase. Thus, in the initial period of the whole vapor deposition cycle, the vapor deposition rate of the first ultraviolet absorbing material is relatively fast and the vapor deposition rate of the second ultraviolet absorbing material is relatively slow, thereby forming the fourth region 34, in which a mass ratio of the first ultraviolet absorbing material to the second ultraviolet absorbing material in the fourth region 34 is X1 that is greater than 1. In the middle period of the whole vapor deposition cycle, the vapor deposition rate of the first ultraviolet absorbing material and the vapor deposition rate of the second ultraviolet absorbing material are similar, thereby forming the fifth region 35, in which a mass ratio of the first ultraviolet absorbing material to the second ultraviolet absorbing material in the fifth region 35 is X2 that is less than X1 and greater than 1. In the final period of the whole vapor deposition cycle, the vapor deposition rate of the first ultraviolet absorbing material is relatively slow and the vapor deposition rate of the second ultraviolet absorbing material is relatively fast, thereby forming the sixth region 36, in which a mass ratio of the first ultraviolet absorbing material to the second ultraviolet absorbing material in the sixth region 36 is X3 that is less than 1. In the ultraviolet shielding layer 3 formed in the above manner, the refractive indexes of the fourth region 34, the fifth region 35, and the sixth region 36 are sequentially decreased, thereby forming an ultraviolet shielding layer 3 having a refractive index gradually decreasing in a direction from proximate to the substrate 1 to away from the substrate 1.

In the technical solution provided by the present disclosure, the ultraviolet shielding layer which is capable of covering at least a portion of the display unit is formed on the display unit, and the ultraviolet shielding layer includes at least two ultraviolet absorbing materials having different ultraviolet absorbing bands. Thus, when the display substrate is subjected to thin film packaging, the ultraviolet shielding layer is capable of absorbing ultraviolet light with different ultraviolet absorbing bands in the chamber in which the packaging process is performed, thereby avoiding the influence of ultraviolet light in the chamber of the packaging process on the light-emitting material layer included in the display unit of the display substrate when the display substrate is packaged. Moreover, when the packaged display substrate is applied in an external environment, the ultraviolet shielding layer in the display substrate is also capable of absorbing ultraviolet light with different wavelength bands in the external environment, thereby avoiding ultraviolet light in the external environment to affect the light-emitting material layer included in the display unit of the display substrate. Therefore, in the technical solution provided by the present disclosure, the ultraviolet shielding layer is capable of absorbing ultraviolet light with different wavelength bands, so that the display substrate can avoid the influence of the ultraviolet light on the light-emitting material layer included therein during the packaging process and during the use, such that the lifetime of the display substrate is well guaranteed.

Unless otherwise defined, technical terms or scientific terms used herein have the normal meaning commonly understood by one skilled in the art in the field of the present disclosure. The words “first”, “second”, and the like used in the present disclosure does not denote any order, quantity, or importance, but rather merely serves to distinguish different components. The “including”, “containing”, and the like used in the present disclosure means that the element or item appeared in front of the word encompasses the element or item and their equivalents listed after the word, and does exclude other elements or items. The word “connected” or “connecting” and the like are not limited to physical or mechanical connections, but may include electrical connections, whether direct or indirect. “On”, “under”, “left”, “right” and the like are only used to represent relative positional relationships, and when the absolute position of the described object is changed, the relative positional relationship may also be changed, accordingly.

It will be understood that when an element, such as a layer, film, region, or substrate, is referred to as being “on” or “under” another element, the element may be directly “on” or “under” another element, or there may be an intermediate element.

In the description of the above embodiments, the specific features, structures, materials or features may be combined in any suitable manner in any one or more embodiments or examples.

The above description is merely the specific embodiment of the present disclosure, but the scope of the present disclosure is not limited thereto. Moreover, any person skilled in the art would readily conceive of modifications or substitutions within the technical scope of the present disclosure, and these modifications or substitutions shall also fall within the protection scope of the present disclosure. Therefore, the protection scope of the present disclosure should be determined by the scope of the claims.

What is claimed is:

1. A display substrate comprising:
a substrate,
a display unit arranged on the substrate,
an ultraviolet shielding layer arranged on a side of the display unit away from the substrate, wherein the ultraviolet shielding layer covers at least a portion of the display unit and comprises at least two ultraviolet absorbing materials having different ultraviolet absorption bands.

2. The display substrate of claim 1, wherein the ultraviolet absorption bands of the at least two ultraviolet absorbing materials are able to cover a wavelength range of 10 nm to 400 nm after being superimposed.

3. The display substrate of claim 1, wherein the at least two ultraviolet absorbing materials have different refractive indexes, and the ultraviolet shielding layer comprises at least two regions sequentially arranged along a direction perpendicular to the substrate, and wherein the at least two regions have different refractive indexes.

4. The display substrate of claim 3, wherein along a direction from proximate to the substrate to away from the substrate, a refractive index of the ultraviolet shielding layer gradually decreases.

5. The display substrate of claim 4, wherein the ultraviolet shielding layer comprises a first ultraviolet absorbing material and a second ultraviolet absorbing material, wherein a refractive index of the first ultraviolet absorbing material is greater than a refractive index of the second ultraviolet absorbing material; and the at least two regions comprise a first region, a second region, and a third region sequentially arranged along a direction from proximate to the substrate to away from the substrate, wherein the first region comprises the first ultraviolet absorption material, the second region comprises the first ultraviolet absorbing material and the second ultraviolet absorbing material, and the third region comprises the second ultraviolet absorbing material.

6. The display substrate of claim 4, wherein the ultraviolet shielding layer comprises a first ultraviolet absorbing material and a second ultraviolet absorbing material, and a refractive index of the first ultraviolet absorbing material is greater than a refractive index of the second ultraviolet absorbing material; and the at least two regions comprises a fourth region, a fifth region, and a sixth region sequentially arranged in a direction sequentially arranged along a direction from proximate to the substrate to away from the substrate, and wherein a mass ratio of the first ultraviolet absorbing material to the second ultraviolet absorbing material in the fourth region is X1 that is greater than 1, a mass ratio of the first ultraviolet absorbing material to the second ultraviolet absorbing material in the sixth region is X3 that is less than 1, and a mass ratio of the first ultraviolet absorbing material to the second ultraviolet absorbing material in the fifth region is X2 that is less than X1 and greater than X3.

7. The display substrate of claim 1, wherein the ultraviolet absorbing material comprises a triphenylamine-based organic material, a material with an aza-aromatic ring structure or a triamine derivative with a carbazole-based benzo-conjugated structure.

8. The display substrate of claim 1, wherein the ultraviolet absorbing material has a refractive index of 1.8 to 2.2.

9. The display substrate of claim 1, wherein the ultraviolet shielding layer covers the entire region of the display unit.

10. A display device comprising the display substrate of claim 1.

11. A method for preparing a display substrate, comprising:
preparing a display unit on the substrate;
forming an ultraviolet shielding layer on a side of the display unit away from the substrate, wherein the ultraviolet shielding layer covers at least a portion of the display unit and comprises at least two ultraviolet absorbing materials having different ultraviolet absorption bands.

12. The method of claim 11, wherein the ultraviolet absorption bands of the at least two ultraviolet absorbing materials are able to cover a wavelength range of 10 nm to 400 nm after being superimposed.

13. The method of claim 11, wherein the forming the ultraviolet shielding layer on the side of the display unit away from the substrate comprises:
forming the ultraviolet shielding layer by vapor deposition of the at least two ultraviolet absorbing materials.

14. The method of claim 13, wherein the forming the ultraviolet shielding layer by vapor deposition of the at least two ultraviolet absorbing materials comprises:
vapor depositing the ultraviolet absorbing material with an evaporation source that is in one-to-one correspondence with the ultraviolet absorbing material to form the ultraviolet shielding layer.

15. The method of claim 14, wherein the at least two ultraviolet absorbing materials have different refractive indexes, and the ultraviolet shielding layer comprises at least two regions sequentially arranged along a direction perpendicular to the substrate, and the at least two regions have different refractive indexes, and wherein the forming the ultraviolet shielding layer comprises:
forming the ultraviolet shielding layer by controlling a vapor deposition rate of each of the evaporation sources.

16. The method of claim 14, wherein the at least two ultraviolet absorbing materials have different refractive indexes, and the ultraviolet shielding layer comprises at least two regions sequentially arranged along a direction perpendicular to the substrate, and the at least two regions have different refractive indexes, and wherein the forming the ultraviolet shielding layer comprises:
forming the ultraviolet shielding layer by controlling a vapor deposition time of each of the evaporation sources.

17. The method of claim 11, wherein the ultraviolet shielding layer comprises at least two regions sequentially arranged along a direction perpendicular to the substrate, and the at least two regions have different refractive indexes, and wherein the forming the ultraviolet shielding layer comprises:
forming the ultraviolet shielding layer by controlling a vapor deposition rate and a vapor deposition time of each of the evaporation sources.

18. The method of claim 15, wherein the at least two ultraviolet absorbing materials comprise a first ultraviolet absorbing material and a second ultraviolet absorbing material, and a refractive index of the first ultraviolet absorbing material is greater than a refractive index of the second ultraviolet absorbing material, and along a direction from proximate to the substrate to away from the substrate, a refractive index of the ultraviolet shielding layer gradually decreases, and wherein the forming the ultraviolet shielding layer comprises:
throughout a first period of a vapor deposition cycle, controlling an evaporation source having the first ultraviolet absorbing material to perform vapor deposition, and an evaporation source having the second ultraviolet absorbing material to stop vapor deposition;
throughout a second period of the vapor deposition cycle, controlling the evaporation source having the first ultraviolet absorbing material and the evaporation source having the second ultraviolet absorbing material to perform vapor deposition together; and
throughout a third period of the vapor deposition cycle, controlling the evaporation source having the first ultraviolet absorbing material to stop vapor deposition, and the evaporation source having the second ultraviolet absorbing material to perform vapor deposition.

19. The method of claim 12, wherein the at least two ultraviolet absorbing materials comprise a first ultraviolet absorbing material and a second ultraviolet absorbing material, with a refractive index of the first ultraviolet absorbing material being greater than a refractive index of the second ultraviolet absorbing material, and along a direction from proximate to the substrate to away from the substrate, a refractive index of the ultraviolet shielding layer gradually decreases, and wherein the forming the ultraviolet shielding layer comprises:
controlling the evaporation source having the first ultraviolet absorbing material and the evaporation source having the second ultraviolet absorbing material to perform vapor deposition together; controlling a vapor deposition rate of the evaporation source having the first ultraviolet absorbing material to gradually decrease; and controlling a vapor deposition rate of the evaporation source having the second ultraviolet absorbing material to gradually increase.

20. The method of claim 13, wherein the forming the ultraviolet shielding layer by vapor deposition of the at least two ultraviolet absorbing materials comprises:
mixing the at least two ultraviolet absorbing materials to prepare a mixed material; and
vapor depositing the mixed material by an evaporation source to form the ultraviolet shielding layer.
